(19) United States
(12) Patent Application Publication
(10) Pub. No.: US 2026/0177643 A1
(43) Pub. Date: Jun. 25, 2026

(54) Adjustable Adapter for Network Device Connector

(71) Applicant: Arista Networks, Inc., Santa Clara, CA (US)

(72) Inventors: Rohan Phadke, Fremont, CA (US); Purav Shah, San Jose, CA (US); Ankush Dhar, Milpitas, CA (US); Jason Gao, Toronto (CA)

(21) Appl. No.: 18/990,507

(22) Filed: Dec. 20, 2024

(51) Int. Cl. G01R 31/70; H04L 49/35

(52) U.S. Cl. CPC G01R 31/70; H04L 49/35

(57) ABSTRACT

An adapter receivable by a network device connector may include a corresponding mating connector and switching circuitry. Different lanes of the mating connector, and consequently different lanes of the network device connector, may be accessible via the switching circuitry at corresponding test connectors. The lanes for access may be selectable using input devices of the adapter. Configured in this manner, external equipment such as test equipment may selectively access the lanes of the network device connector through the adapter.

### BACKGROUND

A network device can include interfaces implemented on port connectors such as card edge connectors. Internal connections to and from the connectors can sometimes be faulty. It may be desirable to detect these faulty connections using test equipment. There can be numerous lanes on a connector that should be individually accessible to the test equipment for characterization.

### BRIEF DESCRIPTION OF THE DRAWINGS

FIG. 1 is a diagram of an illustrative network device having one or more connectors in accordance with some embodiments.

FIG. 2 is a diagram of an illustrative adjustable adapter for a connector in accordance with some embodiments.

FIG. 3 is a diagram of an illustrative adjustable adapter that provides selectable access to different connector lanes in accordance with some embodiments.

FIG. 4 is a diagram of illustrative input devices that change the state of switching circuitry to provide selectable connector lane access in accordance with some embodiments.

FIGS. 5A and 5B are diagrams of illustrative sets of connector lanes that are accessible based on corresponding switching circuitry states in accordance with some embodiments.

FIG. 6 is a cross-sectional side view of an illustrative adjustable adapter receivable by a port having a connector in accordance with some embodiments.

FIG. 7 is a diagram of illustrative exterior-facing adapter components in accordance with some embodiments.

### DETAILED DESCRIPTION

Electrical components may be communicatively coupled to each other using corresponding mating connectors. A connector of a host system such as a network device may include internal signal paths that connect lanes of the connector to other internal components (e.g., network traffic processing components). These lane connections can sometimes be faulty. Accordingly, it may be desirable to detect these faults (e.g., short circuits, open circuits, etc.) using test equipment. However, it can be challenging for the test equipment to access these lanes of the connector individually for characterizing the performance of each lane (e.g., each pair of lanes in a differential signal system).

While test fixtures such as host compliance boards can be used as the interfacing device between the connector for testing and the test equipment, host compliance boards are often designed to route each lane to a corresponding coaxial cable connector, thereby undesirably leading to numerous coaxial cable connectors to connect to for testing and a bulky test fixture. The use of these types of host compliance boards can complicate the testing process for a user and can be susceptible to measurement errors, because the user will need to repeatedly connect cables (i.e., re-cable) to each of the coaxial cable connectors and ensure precise cable mating to the corresponding connector to obtain satisfactory measurements. Additionally, for some applications, the cost of these types of host compliance boards can be prohibitive and the high performance of these types of host compliance boards can be excessive.

To address these issues and/or impart other advantages, an adjustable adapter for connector(s) can be provided. The adjustable adapter may sometimes be referred to herein as an (adjustable) host compliance board or an (adjustable) test fixture, e.g., in the context of testing host system connectors. In some illustrative configurations described herein as examples, the adjustable (connector) adapter, e.g., implemented with adjustable components, may selectively connect different lanes of a connector (e.g., a host system connector) to a corresponding connector (e.g., a test connector such as a coaxial input for test equipment). The adapter may include switching circuitry that provides the selected connections and input devices (e.g., mechanical switches) that control the state of the switching circuitry based on user input. Configured in this manner, the adjustable adapter can simplify testing of connectors, e.g., because no re-cabling is needed to access different lanes of a connector, thereby reducing the likelihood of cabling errors and measurement errors, among other advantages. Additionally, the cost of these types of adjustable adapters can be adapted to the application (e.g., higher performance components such as higher bandwidth switches can be used to improve the performance of the adapter if needed for some applications, while lower performance components such as lower bandwidth switches can be used to lower cost if desired for some applications).

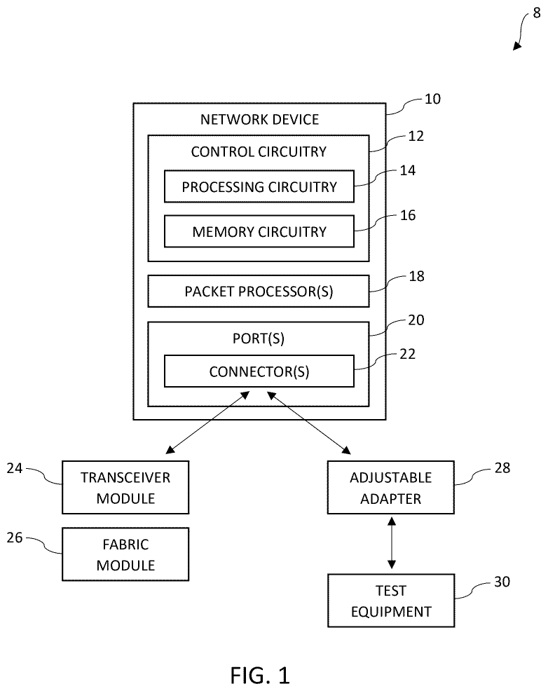

An illustrative system in which an adjustable connector adapter (e.g., of the type described above and generally herein) can be employed is shown in FIG. 1. In the example of FIG. 1, an illustrative system 8 may include one or more network devices 10. Each network device 10 may include or be a switch (e.g., a single-layer (Layer 2) switch or a multi-layer (Layer 2 and Layer 3) switch), a router or gateway, a bridge, a hub, a repeater, a firewall, a wireless access point, a network management device that manages the operation of one or more other network devices, a device serving other networking functions, a device that includes a combination of these functions, or other types of network devices. Multiple such network devices 10 (e.g., of different types and/or having different functions) in system 8 may be present and interconnected therebetween and with other network devices in other network portions to form a communications network that forwards network traffic (e.g., as frames, as packets, and/or in other forms) between end hosts.

A network device 10 may include control circuitry 12 having processing circuitry 14 and memory circuitry 16, one or more packet processors 18, and ports 20, among other components. Network device components may be disposed within and/or mounted to a housing (or chassis) of network device 10. The housing may include an exterior cover (e.g., a metal exterior shell, a plastic exterior shell, etc.) and internal support structures that provide structural support and protection for the components of network device 10 disposed within and/or mounted to the housing. In one illustrative arrangement, network device 10 may be or form part of a modular network device system (e.g., a modular switch system having removably coupled modules usable to flexibly adjust system capabilities such as adjust the network traffic processing capabilities by changing the number of processors, memory, and/or other hardware components, adjust the number of ports, add or remove specialized functionalities, etc.). In another illustrative arrangement, network device 10 may be a fixed-configuration network device (e.g., a fixed-configuration switch having a fixed number of ports and/or a fixed hardware configuration).

Processing circuitry 14 may include one or more processors such as central processing units (CPUs), graphics processing units (GPUs), microprocessors, general-purpose processors, host processors, microcontrollers, digital signal processors, programmable logic devices such as field programmable gate array (FPGA) devices, application specific system processors (ASSPs), application specific integrated circuit (ASIC) processors, and/or other types of processors.

Processing circuitry 14 may run (e.g., execute) a network device operating system and/or other software (including firmware) that is stored on memory circuitry 16. Memory circuitry 16 may include one or more non-transitory (tangible) computer readable storage media that stores the operating system software and/or any other software code. As an example, network device control plane functions may be stored as (software) instructions on the one or more non-transitory computer-readable storage media (e.g., in portion(s) of memory circuitry 20 in network device 10). The corresponding processing circuitry (e.g., one or more processors of processing circuitry 14 in network device 10) may process or execute the respective instructions to perform the corresponding operations.

Memory circuitry 16 may include non-volatile memory (e.g., flash memory, electrically-programmable read-only memory, a solid-state drive, hard disk drive storage, etc.), volatile memory (e.g., static random-access memory or dynamic random-access memory), removable storage devices (e.g., storage devices removably coupled to device 10), and/or other types of memory circuitry. Processing circuitry 14 and memory circuitry 16 as described above may sometimes be referred to collectively as control circuitry 12 (e.g., implementing a control plane of network device 10).

Packet processor(s) 18 may be used to implement a data plane or forwarding plane of network device 10. Packet processor(s) 18 may include one or more processors such as programmable logic devices (e.g., field programmable gate array (FPGA) devices), application specific system processors (ASSPs), application specific integrated circuit (ASIC) processors, central processing units (CPUs), graphics processing units (GPUs), microprocessors, general-purpose processors, host processors, microcontrollers, digital signal processors, and/or other types of processors.

Packet processor 18 may receive incoming data packets via input-output interfaces (e.g., formed from ports 20), parse and analyze the received data packets, process the packets based on packet forwarding decision data (e.g., in a forwarding information base) and/or in accordance with network protocol(s) or other forwarding policy, and forward (or drop) the data packet accordingly. The packet forwarding decision data may be stored on a portion of memory circuitry 20 and/or on other memory circuitry integrated as part of or separate from packet processor 18.

To interact with external devices and equipment, and/or with users, network device 10 may include input-output interfaces formed from corresponding input-output devices. These input-output interfaces may include different types of communication interfaces such as Ethernet interfaces (e.g., formed from one or more Ethernet ports), optical interfaces (e.g., formed from inserted pluggable modules containing optical transceivers), wireless personal area network interfaces, wireless local area network interfaces, and/or other interfaces for connecting device 10 to the Internet, a local area network, a wide area network, a mobile network, generally network device(s) in these networks, and/or other computing equipment (e.g., end hosts, server equipment, etc.). As an example, some input-output interfaces (e.g., those based on wireless communication) may be implemented using wireless communication circuitry (e.g., antennas, transceivers, radios, etc.).

Other input-output interfaces (e.g., those based on wired communication) may be implemented on physical ports such as ports 20. Ports 20 may be configured to physically couple to and electrically connect to corresponding mating connectors of external devices and equipment. Different ports may have different form-factors to accommodate different cables, different modules, different devices, and/or generally different external equipment.

In addition to provide ports 20 for network interfaces (e.g., network interfaces that connect to other network nodes), ports 20 may also be provided for internal network device interfaces, such as backplane interfaces, midplane interfaces, interfaces for connecting to swappable internal network device components, etc.

In the example of FIG. 1, ports 20 may include respective connectors 22. In some illustrative configurations described herein as an example, some ports 20 may be configured to mate with (e.g., physically and electrically connect to) transceiver modules such as transceiver module 24. These ports 20 may sometimes be referred to as pluggable transceiver module ports. In particular, transceiver module 24 may include (electrical or optical) transceiver modules such as pluggable (e.g., removable) transceiver modules (e.g., small form-factor pluggable (SFP) modules, SFP double-density (SFP-DD) modules, dual small form-factor pluggable (DSFP) modules, DSFP double-density (DSFP-DD) modules, quad small form-factor pluggable (QSFP) modules, QSFP double-density (QSFP-DD) modules, octal small form-factor pluggable (OSFP) modules, octal small form-factor extra dense pluggable (OSFP-XD) modules, etc.). An optical (or electrical) transceiver module 24, when plugged into or received in a corresponding port 20, may enable network device 10 to be coupled to another device through a (high-speed) fiber-optic cable (or a high-speed copper cable). In this example, port connector 22 may be a card edge connector (e.g., receptacle or socket) configured to mate with a card edge connector of a transceiver module 24 (e.g., a connector patterned onto an edge of a printed circuit board).

As another example, some ports 20 (e.g., for backplane interfaces of a line card in device 10) may be configured to mate with (e.g., physically and electrically connect to) fabric modules such as fabric modules 26 (sometimes referred to as fabric cards 26). A fabric module 26 may connect multiple line cards to each other via their corresponding backplane interfaces. Accordingly, connectors 22 for these types of ports 20 may be configured to mate with fabric module connectors. Whereas ports 20 configured to receive transceiver modules 24 form network interfaces of device 10, ports 20 configured to receive fabric modules 26 may form (internal) backplane interfaces of device 10.

These types of ports 20 (e.g., for module 24 and for module 26) and other types of ports 20 of device 10 may be communicatively coupled (e.g., electrically connected) to other components of device 10 (e.g., packet processors 18, processing circuitry 14, other network traffic processing components, memory circuitry 16, etc.) via corresponding internal signal paths within device 10. These internal connections may be susceptible to faults, e.g., during manufacturing. Accordingly, it may be desirable to communicatively couple test equipment such as test equipment 30 to a port 20 and its corresponding connector 22 to perform fault detection and/or other types of testing.

In illustrative configurations sometimes described herein as an example, test equipment 30 may include a time-domain reflectometer (TDR). If desired, other types of connectivity and/or signal integrity test equipment (e.g., vector network analysis (VNA) equipment or other test equipment configured to perform time-domain reflectometry) may be used as test equipment 30.

To simplify the testing process for a user, an adjustable adapter 28 may be provided between network device 10 and test equipment 30. Adjustable adapter 28 may have one end that is mated with (e.g., by insertion into) the port 20 and the connector 22 under test and may have another end that provides test connector(s) for connecting to test equipment 30 via corresponding cable(s) (or if desired, via other types of signal paths in implementations in which adapter 28 is implemented as an integral part of test equipment 30). These test connector(s) may provide selectable access to different lanes of connector 22. In the testing application, adjustable adapter 28 may sometimes be referred to as test fixture 28 or as host compliance board 28 (when used to test host system connectors).

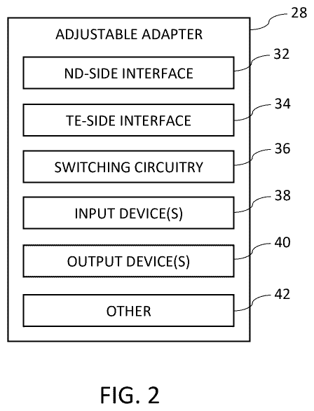

FIG. 2 is an illustrative functional block diagram of an adjustable adapter 28 (e.g., usable in system 8 of FIG. 1). Adapter 28 may include a network-device-side interface 32, a test-equipment-side interface 34, switching circuitry 36, input devices 38, output devices 40, and other components 42.

Network-device-side interface 32 (sometimes generally referred to as a device-under-test (DUT) interface 32) may include a connector configured to mate (e.g., connect) with the corresponding connector 22 of device 10. When the two connectors are mated, each physical lane of the connector for interface 32 may be electrically connected to a corresponding lane of connector 22 of device 10. A portion of the housing for adapter 28 may also form part of interface 32 such that adapter 28 is pluggable into or can otherwise mate with port 20 containing the connector 22. In other words, this portion of the housing may follow the form factor of the module normally received by port 20 and connector 22 during normal network device operations (e.g., when the port 20 is used to forward network traffic).

Test-equipment-side interface 34 (sometimes referred to as test interface 34) may include test connector(s) that facilitate connections to test equipment 30 (e.g., a time-domain reflectometer). In some illustrative configurations described herein as an example, interface 34 may include one or more coaxial connectors (e.g., a pair of coaxial connectors for receiving a test signal as a differential signal pair). Corresponding coaxial cable(s) may be received by the coaxial connectors and used to connect to test equipment 30. In other configurations, other types of connectors (or generally signal paths) can be used to connect interface 34 to test equipment 30 and/or to other types of external equipment (e.g., in applications in which adapter 28 is not used for testing purposes).

Switching circuitry 36 (sometimes referred to as a switch matrix) may be coupled between the connector lanes of interface 32 and the connector(s) of interface 34. Switching circuitry 36 may electrically connect a selected one of the connector lanes of interface 32 to each connector of interface 34 (at each given time). In some illustrative configurations described herein as an example, switching circuitry 36 may include single-pole double-throw switches and single-pole eight-throw switches. If desired, in other configurations, switching circuitry 36 may include any combination of single-pole double-throw switch(es), single-pole four-throw switch(es), single-pole eight-throw switch(es), other single-pole multi-throw switch(es), and/or other types of switches. Switching circuitry 36 may be implemented using and include one or more switch integrated circuits (e.g., a radio-frequency integrated circuit for each (radio-frequency) switch in switching circuitry 36).

To gather input (e.g., user input), adapter 28 may include input devices 38. In particular, switches in switching circuitry 36 may receive control inputs (e.g., control signals) from input devices 38. In some illustrative configurations described herein as an example, input devices 38 may include mechanical switches (e.g., electromechanical switches) such as a toggle switch and a rotary switch. If desired, in other configurations, input devices 38 may include other types of mechanical switches and/or may include other types of user input devices such as buttons, touch sensors, force sensors, etc. Upon receiving input (e.g., user input) the input devices may convey corresponding control inputs to the switches in switching circuitry 36 to update the state of switching circuitry 36, and consequently the electrical connection between the connector lanes of interface 32 and the connector(s) of interface 34.

To provide output (e.g., user output), adapter 28 may include output devices 40. As examples, output devices 40 may include light sources such as status indicator lights, displays, speakers, etc. In some illustrative configurations described herein as an example, adapter 28 may include (status) indicator lights that indicate the power status of adapter 28, the state of switching circuitry 36, and/or the connectivity statuses of interface 32 and/or interface 34, among other information.

These above-mentioned components of adapter 28 are merely illustrative. If desired, adapter 28 may include other components 42 such as one or more substrates (e.g., rigid printed circuit boards, flexible printed circuit substrates, etc.) on which other components of adapter 28 are mounted (e.g., soldered), signal paths (e.g., formed as conductive traces on the substrate(s), formed from connector ribbons, etc.) that communicatively coupled electrical components of adapter 28 to one another, power supply components (e.g., power supply and/or management circuitry) that supply power to certain electrical components of adapter 28 (e.g., switching circuitry 36), and/or a housing or enclosure in which other components of adapter 28 are disposed and/or to which other components of adapter 28 are mounted, as just a few examples.

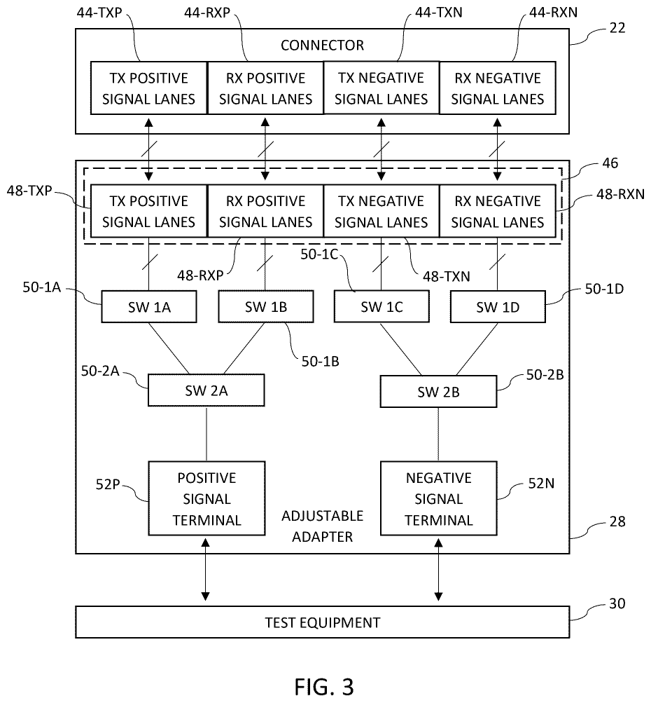

FIG. 3 is a diagram of an illustrative implementation of an adjustable adapter 28 (e.g., as described in connection with FIGS. 1 and 2) configured to interface between a port connector 22 (e.g., as described in connection with FIG. 1) and test equipment 30 (e.g., as described in connection with FIG. 1). As shown in FIG. 3, port connector 22 may include a plurality of signal lanes 44 (e.g., a plurality of conductive traces, contacts, and/or other structures) each configured to convey a corresponding signal. In the example of FIG. 3, port connector 22 may be configured to facilitate full-duplex communication and/or pairs of signal lanes 44 may be used to convey differential signals (e.g., differential signal pairs). As such, port connector 22 may include transmit (differential) signal lanes such as positive signal transmit lanes 44-TXP and negative signal transmit lanes 44-TXN, and may include receive (differential) signal lanes such as positive signal receive lanes 44-RXP and negative signal receive lanes 44-RXN.

Adapter 28 may include a connector 46 (e.g., forming DUT interface 32 in FIG. 2) that mates with connector 22. For example, connector 46 may be a printed circuit board edge connector (e.g., a male edge connector), while connector 22 may be an edge connector (receptacle) (e.g., a female edge connector). Each lane 48 of connector 46 may be physically and electrically coupled to a corresponding lane 44 of connector 22 (when connector 46 is inserted into or otherwise mated with connector 22). Accordingly, in the example of FIG. 3, connector 46 may similarly include transmit (differential) signal lanes such as positive signal transmit lanes 48-TXP and negative signal transmit lanes 48-TXN, and may include receive (differential) signal lanes such as positive signal receive lanes 48-RXP and negative signal receive lanes 48-RXN.

As shown in the example of FIG. 3, the switching circuitry of adapter 28 (e.g., switching circuitry 36 in FIG. 2) may be implemented using two layers of switches 50 (e.g., radio-frequency switches), including a first layer of switches 50-1A, 50-1B, 50-1C, and 50-1D and a second layer of switches 50-2A and 50-2B. These switches may electrically connect different lanes 48 to one or more corresponding test connectors that facilitate further connection(s) to test equipment 30.

In particular, in the example of lanes 44 and 48 conveying differential signals, adapter 28 of FIG. 3 may include a positive signal terminal 52P and a negative signal terminal 52N forming the test interface (e.g., test interface 34 in FIG. 2). In some illustrative configurations, positive signal terminal 52P may be provided as part of a first coaxial cable connector (e.g., a receptacle configured to receive a first coaxial cable connecting to test equipment 30) and negative signal terminal 52N may be provided as part of a second coaxial cable connector (e.g., a receptacle configured to receive a second coaxial cable connecting to test equipment 30). Test equipment 30 may inject or input test signals (e.g., differential test signals) into terminals 52P and 52N (e.g., the two coaxial connectors) to test one pair of differential signal lanes 44 at a time (by presenting the test signal at the corresponding connected pair of differential signal lanes 48).

The type of switches used to implement the first layer of switches (e.g., the number of throws of these switches) may depend on the configuration of lanes 48 (e.g., which itself is dependent on the configuration of lanes 44). In a configuration in which there are eight lanes 48-TXP, eight lanes 48-RXP, eight lanes 48-TXN, and eight lanes 48-RXN, each of switches 50-1A, 50-1B, 50-1C, and 50-1D in the first layer may be a single-pole eight-throw switch, with eight (output) terminals respectively coupled to the eight lanes of that set of lanes and a single (input) terminal selectively connected to one of the eight (output) terminals based on the state of that switch. In other words, the number of lanes in each set of lanes may be equal to the number of throws of the coupled switch.

The second layer of switches 50-2A and 50-2B may each be a single-pole double-throw switch. Accordingly, switch 50-2A may have a first (output) terminal coupled to switch 50-1A, may have a second (output) terminal coupled to switch 50-1B, and a third (input) terminal selectively connected to the first or second (output) terminal of switch 50-2A based on the state of switch 50-2A. The third switch terminal may be coupled to positive signal terminal 52P. Switch 50-2B may have a first (output) terminal coupled to switch 50-1C, may have a second (output) terminal coupled to switch 50-1D, and a third (input) terminal selectively connected to the first or second (output) terminal of switch 50-2B based on the state of switch 50-2B. The third switch terminal may be coupled to negative signal terminal 52N.

Configurations in which switches 50-1A, 50-1B, 50-1C, 50-1D, 50-2A, and 50-2B are each a single-pole multi-throw switch implemented using a corresponding radio-frequency integrated circuit are sometimes described herein as an example. As an example, these switches (e.g., switching circuitry 36) may collectively exhibit a bandwidth on the order of gigahertz (GHz), e.g., between 1-10 GHz. The use of this bandwidth may be satisfactory for some applications, while reducing costs (when compared with higher bandwidth switching circuitry implementations). If desired, more than two layers of switches (e.g., three layers of switches, four layers of switches, etc.) may be used to implement switching circuitry 36 (and/or other switching matrix implementations may be used) to further increase the bandwidth of switching circuitry 36.

Configured in the manner shown in FIG. 3, a selected one of lanes 48-TXP and lanes 48-RXP may be electrically connected to positive signal terminal 52P via switching circuitry (e.g., the two layers of switches), at each given time. Similarly, a selected one of lanes 48-TXN and lanes 48-RXN may be electrically connected to negative signal terminal 52N via switching circuitry (e.g., the two layers of switches), at each given time. Accordingly, test equipment 30 may input a desired test differential signal pair into terminals 52P and 52N. The test signal pair may be conveyed to the selected (and electrically connected) pair of positive and negative signal lanes of connector 46 and consequently conveyed to the corresponding (electrically connected) pair of positive and negative signal lanes of connector 22 (e.g., to test for connectivity issues of network device 10 associated the signal lanes of connector 22 being tested).

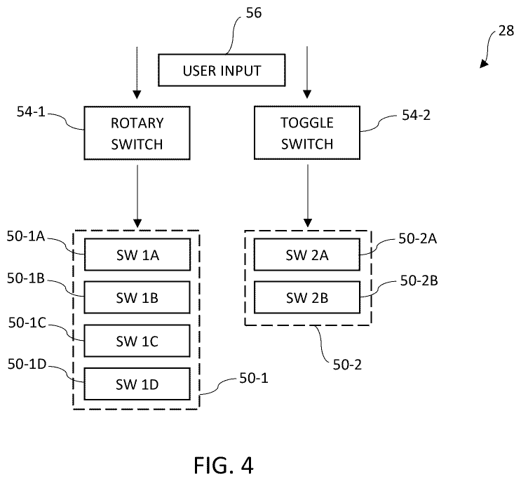

The switch state of the switching circuitry of adapter 28 and consequently the pair of the positive and negative signal lanes 48 (and consequently, lines 44) accessible via (e.g., electrically connected to) terminals 52P and 52N may be controlled based on (user) input devices. FIG. 4 is a diagram of illustrative input devices of adapter 28 (e.g., input devices 38 in FIG. 2) that facilitate the connector lane selection (e.g., to enable test equipment 30 to test different lanes in sequence).

In the example of FIG. 4, adapter 28 may include an electromechanical rotary switch 54-1 (e.g., as a first input device 38) and an electromechanical toggle switch 54-2 (e.g., as a second input device 38). Switches 54-1 and 54-2 may be configured to receive user input 56 (e.g., user input that rotates switch 54-1, user input that toggles switch 54-1, etc.). Responsive to corresponding user input 56, switches 54-1 and 54-2 may provide corresponding control outputs (e.g., control signals) to the switches of switching circuitry 36 (e.g., described in connection with FIG. 3).

As shown in FIG. 4, the control outputs of rotary switch 54-1 may be received (as control inputs) by the first layer of switches 50-1 and control the state of the first layer of switches 50-1. In some illustrative configurations sometimes described herein as an example, the same control input from rotary switch 54-1 may be received by each of switches 50-1A, 50-1B, 50-1C, and 50-1D to place and operate each of these switches in the same state. In particular, rotary switch 54-1 may exhibit a number of states (e.g., eight rotational states) that match the number of throws (e.g., eight throws) of each of switches 50-1A, 50-1B, 50-1C, and 50-1D. When a user provides input 56 that rotates switch 54-1 to a given rotational state, a control signal from switch 54-1 may place each of switches 50-1A, 50-1B, 50-1C, and 50-1D in a corresponding state in which a corresponding output terminal is connected to the single input terminal.

As further shown in FIG. 4, control outputs of toggle switch 54-2 may be received (as control inputs) by the second layer of switches 50-2 and control the state of the second layer of switches 50-2. In some illustrative configurations sometimes described herein as an example, the same control input from toggle switch 54-2 may be received by each of switches 50-2A and 50-2B to place and operate each of these switches in the same state. In particular, toggle switch 54-1 may exhibit a number of states (e.g., two toggling states) that match the number of throws (e.g., two throws) of each of switches 50-2A and 50-2B. When a user provides input 56 that toggles switch 54-2 to a given state, a control signal from switch 54-2 may place each of switches 50-2A and 50-2B in a corresponding state in which a corresponding output terminal is connected to the single input terminal.

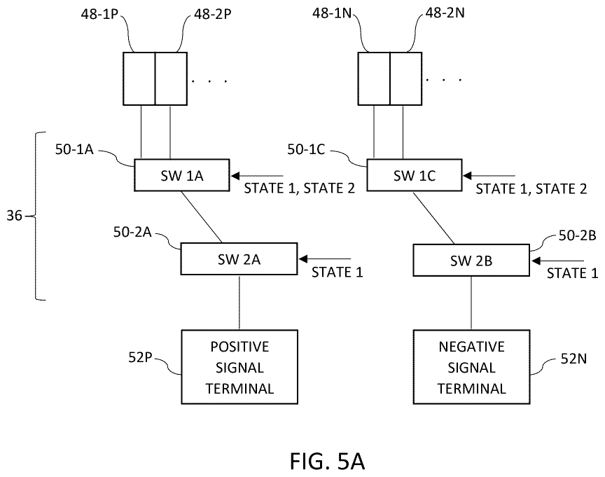

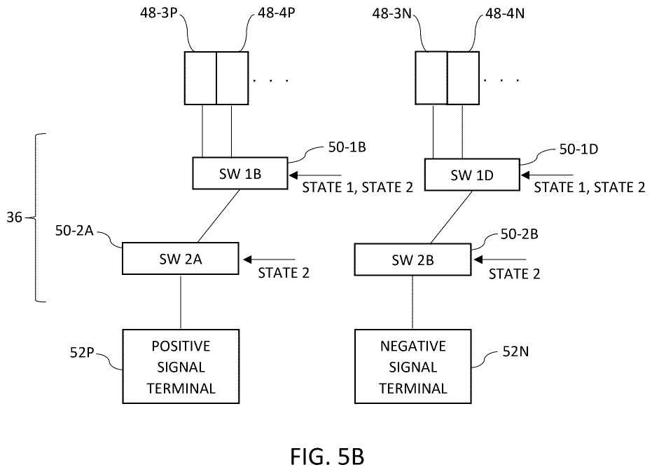

FIGS. 5A and 5B show illustrative connections being made by switching circuitry 36 between selected lanes 48 of connector 46 (e.g., at interface 32 in FIG. 2, coupled to connector 22 in FIG. 3, etc.) and positive and negative signal terminals 52P and 52N (e.g., at interface 34 in FIG. 2, coupled to test equipment 30 in FIG. 3, etc.). While present in switching circuitry 36, switches 50-1B and 50-1D have been omitted from FIG. 5A and switches 50-1A and 50-1C have been omitted from FIG. 5B, in order not to unnecessarily obscure the embodiments described in connection with FIGS. 5A and 5B.

In an illustrative first state of switching circuitry 36 shown in FIG. 5A, switches 50-1A and 50-1C may each receive the same control input (e.g., from rotary switch 54-1) and operate in a first state. When operating in the first state, switch 50-1A may connect a first lane 48-1P such as a positive signal transmit lane 48-TXP in FIG. 3 (e.g., at a first output terminal of switch 50-1A) to switch 50-2A (e.g., at the input terminal of switch 50-1A). When operating in the first state, switch 50-1C may connect a first lane 48-1N such as a negative signal transmit lane 48-TXN in FIG. 3 (e.g., at a first output terminal of switch 50-1C) to switch 50-2B (e.g., at the input terminal of switch 50-1C). In this illustrative first state of switching circuitry 36 shown in FIG. 5A, switches 50-2A and 50-2B may each receive the same control input (e.g., from toggle switch 54-2) and operate in a first state. When operating in the first state, switch 50-2A may connect switch 50-1A (e.g., at a first output terminal of switch 50-2A) to positive signal terminal 52P (e.g., at the input terminal of switch 50-2A). When operating in the first state, switch 50-2B may connect switch 50-1C (e.g., at a first output terminal of switch 50-2B) to negative signal terminal 52N (e.g., at the input terminal of switch 50-2B).

In an illustrative second state of switching circuitry 36 shown in FIG. 5A, switches 50-1A and 50-1C may each receive the same control input (e.g., from rotary switch 54-1) and operate in a second state. When operating in the second state, switch 50-1A may connect a second lane 48-2P such as another positive signal transmit lane 48-TXP in FIG. 3 (e.g., at a second output terminal of switch 50-1A) to switch 50-2A (e.g., at the input terminal of switch 50-1A). When operating in the second state, switch 50-1C may connect a second lane 48-2N such as another negative signal transmit lane 48-TXN in FIG. 3 (e.g., at a second output terminal of switch 50-1C) to switch 50-2B (e.g., at the input terminal of switch 50-1C). In this illustrative second state of switching circuitry 36 shown in FIG. 5A, switches 50-2A and 50-2B may each receive the same control input (e.g., from toggle switch 54-2) and operate in the first state. When operating in the first state, switch 50-2A may connect switch 50-1A (e.g., at a first output terminal of switch 50-2A) to positive signal terminal 52P (e.g., at the input terminal of switch 50-2A). When operating in the first state, switch 50-2B may connect switch 50-1C (e.g., at a first output terminal of switch 50-2B) to negative signal terminal 52N (e.g., at the input terminal of switch 50-2B).

In an illustrative third state of switching circuitry 36 shown in FIG. 5B, switches 50-1B and 50-1D may each receive the same control input (e.g., from rotary switch 54-1) and operate in a first state (e.g., the same first state of switches 50-1A and 50-1C described in connection with FIG. 5A when all four switches receive the same control input). When operating in the first state, switch 50-1B may connect a first lane 48-3P such as a positive signal receive lane 48-RXP in FIG. 3 (e.g., at a first output terminal of switch 50-1B) to switch 50-2A (e.g., at the input terminal of switch 50-1B). When operating in the first state, switch 50-1D may connect a first lane 48-3N such as a negative signal receive lane 48-RXN in FIG. 3 (e.g., at a first output terminal of switch 50-1D) to switch 50-2B (e.g., at the input terminal of switch 50-1D). In this illustrative third state of switching circuitry 36 shown in FIG. 5B, switches 50-2A and 50-2B may each receive the same control input (e.g., from toggle switch 54-2) and operate in a second state. When operating in the second state, switch 50-2A may connect switch 50-1B (e.g., at a second output terminal of switch 50-2A) to positive signal terminal 52P (e.g., at the input terminal of switch 50-2A). When operating in the second state, switch 50-2B may connect switch 50-1D (e.g., at a second output terminal of switch 50-2B) to negative signal terminal 52N (e.g., at the input terminal of switch 50-2B).

In an illustrative fourth state of switching circuitry 36 shown in FIG. 5B, switches 50-1B and 50-1D may each receive the same control input (e.g., from rotary switch 54-1) and operate in a second state (e.g., the same second state of switches 50-1A and 50-1C described in connection with FIG. 5A when all four switches receive the same control input). When operating in the second state, switch 50-1B may connect a second lane 48-4P such as another positive signal receive lane 48-RXP in FIG. 3 (e.g., at a second output terminal of switch 50-1B) to switch 50-2A (e.g., at the input terminal of switch 50-1B). When operating in the second state, switch 50-1D may connect a second lane 48-4N such as another negative signal receive lane 48-RXN in FIG. 3 (e.g., at a second output terminal of switch 50-1D) to switch 50-2B (e.g., at the input terminal of switch 50-1D). In this illustrative fourth state of switching circuitry 36 shown in FIG. 5B, switches 50-2A and 50-2B may each receive the same control input (e.g., from toggle switch 54-2) and operate in the second state. When operating in the second state, switch 50-2A may connect switch 50-1B (e.g., at a second output terminal of switch 50-2A) to positive signal terminal 52P (e.g., at the input terminal of switch 50-2A). When operating in the second state, switch 50-2B may connect switch 50-1D (e.g., at a second output terminal of switch 50-2B) to negative signal terminal 52N (e.g., at the input terminal of switch 50-2B).

These examples in connection with FIGS. 5A and 5B illustrate how four different pairs of lanes 48 (and consequently the four corresponding pairs of lanes 44, when connector 46 is mated with connector 22) may be separately (e.g., sequentially) accessible at positive and negative signal terminals 52P and 52N by updating the state of switching circuitry 36 to the four described states of switching circuitry 36. In an analogous manner, switching circuitry 36 may exhibit a sufficient number of states to enable each lane 48 (and consequently each lane 44) to be accessible, e.g., as differential pairs, at positive and negative signal terminals 52P and 52N. Accordingly, user input 56 (FIG. 4) received by electromechanical switches 54-1 and 54-2 may place switching circuitry 36 in each of these states such that test equipment 30 can selectively access (sequentially) each lane 48 (and consequently each lane 44).

Illustrative configurations in which connectors 22 and 46, connector lanes 44 and 48, other components of adapter 28, and test equipment 30 are configured to handle differential signals (e.g., with differential lane pairs, differential signal paths, differential signal terminals, etc.) are sometimes described herein as examples. If desired, connectors 22 and 46, connector lanes 44 and 48, other components of adapter 28, and test equipment 30 may be configured to handle single-ended signals (e.g., include components such as lanes, terminals, paths, etc. for convey signal-ended signals).

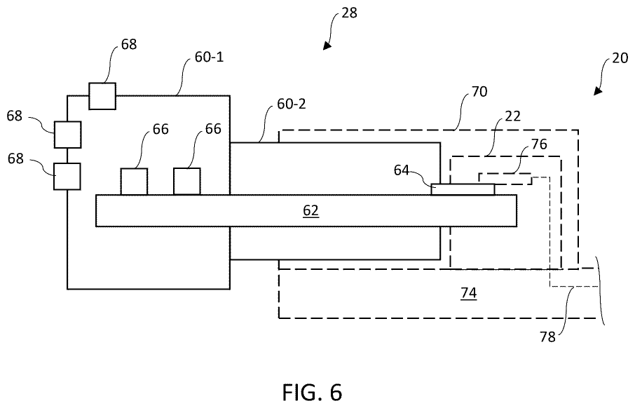

FIG. 6 is a cross-sectional side view of an illustrative adjustable adapter 28 (e.g., as described in some embodiments in connection with FIGS. 1-5) when inserted into an illustrative port 20 having a corresponding connector 22. Components of port 20 and the host system (e.g., network device 10) that includes port 20 are shown by dashed lines in FIG. 6, whereas components of adapter 28 are shown by solid lines in FIG. 6.

As shown in the example of FIG. 6, adapter 28 may include a housing (sometimes referred to as a frame or enclosure) having a first (main) portion 60-1 and a second (protruding) portion 60-2. Protruding portion 60-2 may have a formfactor or generally dimensions that mate with a corresponding cage 70 (sometimes referred to as an enclosure 70) of port 20. Cage 70 may overlap connector 22 of port 20. In particular, cage 70 may surround a cavity region (in which connector 22 is disposed) with an opening on one side to facilitate insertion of external devices (e.g., adapter 28, pluggable optical transceiver module 24, etc.). Cage 70 may serve as a guide to receive external devices and facilitate the alignment and therefore the proper connection between the external devices (e.g., a card edge on adapter 28) and port connector 22 (e.g., a corresponding card edge receptacle). If desired, other guide and/or alignments structures may be included in addition to cage 70 or as part of cage 70 (e.g., surface features on cage 70).

Adapter 28 may include a printed circuit substrate 62 (e.g., a printed circuit board 62). Printed circuit substrate 62 may extend across housing portions 60-1 and 60-2. An edge portion of substrate 62 may protrude beyond housing portion 60-2 and/or generally be exposed (e.g., for insertion into external equipment). Conductive traces 64 forming electrical contacts (e.g., also serving as physical contacts) may be formed (e.g., patterned) onto the edge portion of substrate 62. These conductive traces 64 may form lanes 48 of adapter 28 and facilitate (physical and electrical) connection with corresponding lanes 44 (of connector 22) formed from conductive structures 76 (e.g., conductive contacts, conductive traces, conductive pins, etc.), when the connector of adapter 28 is inserted into connector 22. Cage 70 and connector 22 may be mounted on a printed circuit substrate 74 of the host system (e.g., of network device 10).

Signal paths 78 may communicatively couple conductive structures 76 (e.g., lines 44 of connector 22) to other components of the host system (e.g., other components of device 10 as described in connection with FIG. 1 such as processing circuitry 14, memory circuitry 16, packet processor(s) 18, etc.). As an example, test equipment 30 may, through adapter 28, test the connectivity and integrity of connector 22 (e.g., lanes 44, conductive structures 76, etc.), signal paths 78, and downstream connections and components on the host system.

In some illustrative configurations described herein as examples, cage 70, connector 22, and other components of port 20 may be configured to receive one or more types of pluggable transceiver modules (e.g., optical transceiver modules, such as OSFP-XD modules, OSFP modules, QSFP-DD modules, QSFP modules, DSFP-DD modules, DSFP modules, SFP-DD modules, SFP modules, etc., that are configured in a manner compatible with or in compliance with corresponding standardized specifications for these modules). Accordingly, housing portion 60-2, substrate 62, conductive traces 64, and/or other components of adapter 28 that mates with or otherwise engages with cage 70, connector 22, and other components of port 20 may similarly be configured in a manner compatible with or in compliance with the standardized specification(s) for the corresponding type(s) of pluggable transceiver modules.

These examples are merely illustrative. If desired, housing portion 60-2, substrate 62, conductive traces 64, and/or other components of adapter 28 may engage with other types of ports and/or connectors (e.g., backplane interface ports configured to receive fabric modules 26). When used in these examples, adapter 28 may still facilitate simplified testing of these other port connectors and their corresponding connections using test equipment 30.

Some components 66 of adapter 28 (e.g., as described in connection with FIG. 2) may be mounted or otherwise provided on substrate 62 (e.g., in housing portion 60-1 and/or in housing portion 60-2, on a top surface of substrate 62, on a bottom surface of substrate 62, etc.). As just a few illustrative examples, these components 66 may include switching circuitry 36 (e.g., the one or more radio-frequency integrated circuits implementing switches 50-1 and 50-2 of switching circuitry 36), power supply circuitry, and signal paths formed from (additional) conductive traces on substrate 62 (e.g., signal paths communicatively coupling the power supply circuitry to active components such as switching circuitry 36, communicatively coupling connector lanes 44 to switching circuitry 36, and/or generally communicatively coupling suitable components of adapter 28 to one another).

Some components 68 of adapter 28 may be mounted to the housing of adapter 28 and/or be exterior-facing components (e.g., that protrude through the housing to the exterior of adapter 28). These components 68 may still be communicatively coupled to components 66 and/or printed circuit substrate 62 (e.g., conductive traces thereon) on the interior of adapter 28.

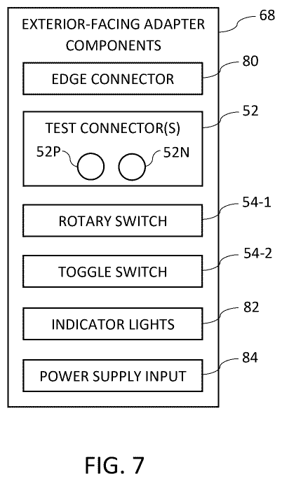

FIG. 7 is a diagram of illustrative components of adapter 28 may be implemented as exterior-facing components 68 that are exposed to the exterior of adapter 28 and/or that are generally (readily) accessible by users and/or external devices and equipment. In particular, exterior-facing components 68 of adapter 28 may include an edge connector 80 (e.g., forming interface 32 in FIG. 2, an illustrative implementation of connector 46 in FIG. 3, implemented using conductive traces 76 on an edge portion of substrate 62 in FIG. 6). Edge connector 80 may be exposed to facilitate insertion into and connection with the corresponding connector 22 of FIG. 6.

Exterior-facing components 68 of adapter 28 may include test connector(s) 52 (e.g., forming interface 34 in FIG. 2 that facilitates connection to test equipment 30) such as a first coaxial connector that include positive signal terminal 52P and a second coaxial connector that includes negative signal terminal 52N. The coaxial connectors may sometimes be referred to as coaxial inputs in the context of test signal injection by test equipment 30 into these coaxial connectors. Providing connectors 52 as exterior-facing components facilitates easy connections (e.g., cabling, using coaxial cables) to connectors 52 for connecting to test equipment 30.

Exterior-facing components 68 of adapter 28 may include electromechanical switches such as rotary switch 54-1 and toggle switch 54-2. Providing these electromechanical switches as exterior-facing components may facilitate ease of user input (e.g., rotation of rotary switch 54-1 and toggling of toggle switch 54-2).

Exterior-facing components 68 of adapter 28 may include indicator lights 82. These indicator lights 82 may provide easily viewable user output (e.g., indicative of the operating status of adapter 28 and/or its components).

Exterior-facing components 68 of adapter 28 may include power supply input (terminal) 84 (e.g., for a 5-volt power supply) configured to receive a power supply cable for powering the components of adapter 28. As an example, the power supply circuitry may receive a power supply voltage from power supply input terminal 84 (from the connected power supply cable cable) and distribute the received power supply voltage to suitable adapter components.

The foregoing is merely illustrative and various modifications can be made to the described embodiments. The foregoing embodiments may be implemented individually or in any combination.

What is claimed is:

1. An adjustable adapter configured to mate with a network device port, the adapter comprising:
a first connector having a plurality of lanes and configured to mate with a corresponding connector of the network device port;
one or more additional connectors having one or more terminals;
switching circuitry coupled between the plurality of lanes and a terminal of the one or more terminals; and
one or more input devices configured to receive user input, based on which the switching circuitry is configured to connect different lanes of the plurality of lanes of the first connector to the terminal of the one or more additional connectors.

2. The adjustable adapter defined in claim 1, wherein the one or more connectors comprise a test connector, with the terminal, configured to receive a test signal from test equipment.

3. The adjustable adapter defined in claim 2, wherein the test equipment is configured to perform time-domain reflectometry.

4. The adjustable adapter defined in claim 1, wherein the plurality of lanes comprise pairs of positive and negative signal lanes that convey differential signals, wherein the one or more additional connectors comprise a second connector having the terminal, wherein the terminal is a positive signal terminal, wherein the one or more additional connectors comprise a third connector having a negative signal terminal, and wherein the positive and negative signal terminals convey a differential signal pair.

5. The adjustable adapter defined in claim 4, wherein the switching circuitry comprises a first set of switches coupled between the positive signal lanes and the positive signal terminal, and comprises a second set of switches coupled between the negative signal lanes and the negative signal terminal.

6. The adjustable adapter defined in claim 5, wherein the one or more input devices comprise a toggle switch configured to receive the user input and configured to provide control inputs to at least some of the first set of switches and at least some of the second set of switches.

7. The adjustable adapter defined in claim 6, wherein the input devices further comprises a rotary switch configured to receive the user input and configured to provide control inputs to at least some of the first set of switches and at least some of the second set of switches.

8. The adjustable adapter defined in claim 1, wherein the one or more input devices are configured to, based on first user input, operate the switching circuitry in a first state in which a first lane of the plurality of lanes is connected to the terminal of the one or more connectors via the switching circuitry, and wherein the one or more input devices are configured to, based on second user input, operate the switching circuitry in a second state in which a second lane of the plurality of lanes is connected to the terminal of the one or more connectors via the switching circuitry.

9. The adjustable adapter defined in claim 8, wherein the first lane and the second lane are both signal transmit lanes or signal receive lanes.

10. The adjustable adapter defined in claim 8, wherein the first lane is a signal transmit lane and wherein the second lane is a signal receive lane.

11. The adjustable adapter defined in claim 1, wherein the network device port, with which the adjustable adapter is configured to mate, is a network interface port.

12. The adjustable adapter defined in claim 11, wherein the network interface port, with which the adjustable adapter is configured to mate, is configured to receive a pluggable optical transceiver module.

13. The adjustable adapter defined in claim 1, wherein the network device port, with which the adjustable adapter is configured to mate, is a backplane interface port.

14. The adjustable adapter defined in claim 1 further comprising:
one or more output devices;
a housing, wherein the one or more connectors, the one or more input devices, and the one or more output devices are mounted to the housing;
a substrate in the housing, wherein the switching circuitry is mounted to the substrate and wherein the plurality of lanes are formed from conductive traces on the substrate;
power supply circuitry mounted to the substrate and configured to supply power to the switching circuitry; and
signal paths that communicatively couple the one or more input devices to the switching circuitry.

15. A host compliance board comprising:
a printed circuit substrate;
a first connector on the printed circuit substrate and having a plurality of lanes that include positive signal lanes and negative signal lanes for conveying differential signal pairs;
a first coaxial connector having a positive signal terminal;
a second coaxial connector having a negative signal terminal, wherein the positive and negative signal terminals convey a differential signal pair; and
switching circuitry mounted to the printed circuit substrate, configured to connect a selected one of the positive signal lanes to the positive signal terminal of the first coaxial connector, and configured to connect a selected one of the negative signal lanes to the negative signal terminal of the second coaxial connector.

16. The host compliance board defined in claim 15 further comprising:
one or more input devices, wherein the selected positive signal lane and the selected negative signal lane are selected based on user input received by the one or more input devices.

17. The host compliance board defined in claim 16, wherein the first and second coaxial connectors are test connectors configured to receive a test signal as the differential signal pair from test equipment.

18. A test fixture comprising:
a housing having a portion configured to mate with a port for a pluggable optical transceiver module;
a printed circuit substrate;
a first connector on the printed circuit substrate and having a plurality of lanes that include positive signal lanes and negative signal lanes for conveying differential signal pairs;
one or more test connectors having a positive signal terminal and a negative signal terminal, wherein the positive and negative signal terminals are configured to receive a test signal as a differential signal pair; and
switching circuitry mounted to the printed circuit substrate, configured to connect a selected one of the positive signal lanes to the positive signal terminal of the first coaxial connector, and configured to connect a selected one of the negative signal lanes to the negative signal terminal of the second coaxial connector.

19. The test fixture defined in claim 18 further comprising:
a plurality of mechanical switches, wherein the selected positive signal lane and the selected negative signal lane are selected based on user input received by the plurality of mechanical switches.

20. The test fixture defined in claim 18, wherein the first connector comprises an edge connector, wherein the plurality of lanes are formed from conductive traces on an edge portion of the printed circuit substrate and wherein the test connectors comprise a first coaxial connector having the positive signal terminal and comprises a second coaxial connector having the negative signal terminal.
